(19) United States
(12) Patent Application Publication
(10) Pub. No.: US 2010/0078795 A1
(43) Pub. Date: Apr. 1, 2010

(54) ELECTRONIC DEVICE

(75) Inventors: Ronald Dekker, Eindhoven (NL); Freddy Roozeboom, Eindhoven (NL); Peter Notten, Eindhoven (NL); Antonius Lucien Adrianus Maria Kemmeren, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/993,516

(22) PCT Filed: Jun. 28, 2006
(86) PCT No.: PCT/IB06/52152

§ 371 Date: Dec. 21, 2007

(30) Foreign Application Priority Data
Jul. 1, 2005 (EP) 05106028.3

(51) Int. Cl. H01L 23/538; H01L 23/482

(52) U.S. Cl. 257/690; 257/723; 257/528; 257/E23.169

(57) ABSTRACT

The electronic device comprises a semiconductor substrate (10) with at a first side (1) a circuit of semiconductor elements (20). The substrate (10) is present between a carrier (40) and an encapsulation (70), so that the first side (1) of the substrate (10) faces the carrier (40). The circuit of semiconductor elements (20) is coupled with conductor tracks (25) to a metallization (82) in a groove (80) in the encapsulation (70), which metallization (82) extends to terminals (90) at an outside of the encapsulation (70). At least one further electrical element (120) is defined between the first side (1) of the semiconductor substrate (10) and the encapsulation (70). This further element (120) is provided with at least one conductor track (65) extending to the metallization (82) in the groove (80) so as to incorporate the further element (120) in the circuit of semiconductor elements (20) on the first side (1) of the substrate (10).

The invention relates to an electronic device comprising a semiconductor substrate having a first side, at which first side a plurality of electrical elements are defined, which substrate is present between a carrier and an encapsulation, so that the first side of the substrate faces the carrier, wherein conductor tracks are present on the first side of the semiconductor substrate and metallized grooves are present in the encapsulation, extending through the substrate to the carrier and being electrically coupled to said conductor tracks, for connecting the elements to terminals that have been defined on an outside of the encapsulation.

Such an electronic device is known from U.S. Pat. No. 6,040,235. The known device is in use for optical packages, for which reason both the carrier and the encapsulation comprise a glass plate. The packaging of the device starts with the adhesion of the semiconductor substrate with on the first side the plurality of electric elements to the carrier. Thereafter, the semiconductor substrate is thinned and it is selectively removed by etching in the separation lanes. Subsequently, it is covered with an adhesive, which also fills the cavities created by the selective etching, and with the glass plate. Then grooves are made in the separation lanes. These grooves extend through the adhesive into the carrier. In this step, conductor tracks present at the first side of the substrate are cut through. In the next step, the groove is metallized and the conductor tracks therein are coupled electrically to the metallization in the groove. This leads to the formation of so called T-shaped contacts. Now there is a connection from the electrical elements to the terminals. Final steps of the packaging are then carried out, which include the provision of a solder mask and solder balls on the terminals, and the separation of the carrier into individual devices.

It is a disadvantage of the device that its packaging technique is relatively expensive for the functionality, except in the case of optical packages, where the light passes the glass and additionally a backside illumination can be provided. And although it is a wafer scale technology, it is not cost competitive with the technology in which a rerouting layer is applied on top of the passivation, and solder bumps are applied thereon. Inherently, this packaging technique has however the advantage that the size of the solder balls can be reduced; as the coefficient of thermal expansion of glass is nearer to that of a printed circuit board than the coefficient of silicon, the needed compensation is smaller. The smaller size of the solder balls again has the advantage that the package can have more terminals.

It is therefore an object of the invention to provide an electronic device of the kind mentioned in the opening paragraph, wherein the functionality of the package is in proportion to the package price.

This object is achieved in that at least one further electrical element is defined between the first side of the semiconductor substrate and the encapsulation, which further element is provided with at least one conductor track extending to the groove and being electrically coupled to the metallization of the groove so as to interconnect the further element to at least one of the elements on the first side of the substrate.

According to the invention, the functionality of the package is increased in that one or more further electrical elements are defined at a surface that is present in the package. The further electrical element is then connected to one or more elements on the first side of the substrate without the need for an additional interconnect that is to be made with a separate process. This allows an increase in functionality, while the surface area does not increase.

It is observed that it is known from U.S. Pat. No. 6,506,664 to stack a plurality of wafers and provide connections to the terminals through a metallized groove. That principle however does not lead to any acceptable solution. It actually only increases one of the problems of the package: much more terminals are needed in that case. Since evidently the available space is limited, the maximum number of terminals will be relatively low in comparison with the provided wafer area, and thus the number of electrical elements.

In comparison thereto, the invention proposes the use of surfaces available within the package to include elements that need a comparatively large surface area and which are desired for a proper functioning of the circuit on the first side of the substrate.

In a first embodiment, the encapsulation comprises a plate at one face thereof components are provided. This face is particularly the one that faces the second side of the semiconductor substrate. The plate is most suitably a glass plate, but is not limited thereto. Components that may be suitably provided hereon are for instance sensors and switches made on the basis of thin film transistors. Particularly good results have been obtained with the use of low temperature polysilicon. Alternatively, one may provide inductors, thin film capacitors, resistors, as well as networks of passive components.

In a specific modification, the further element is at least one magnetoresistive sensor. Such sensors enable precise measurements of position in one, two or even three dimensions, but also of changes in velocity. The sensors are commonly integrated into a Wheatstone bridge. In this modification, it is allowed to obtain a small package that both comprises the sensor and the control circuitry. That is highly desirable for applications of magnetoresistive sensors in mobile phones, such as a GPRS sensor or a magnetic joystick. The plate could be a silicon substrate, but a glass substrate is not excluded.

In a further specific modification, the further element is at least one bulk acoustic wave filter. These filters are in use as narrow bandpass filters at particularly higher frequencies, at which the surface acoustic wave filters do not work properly. As such, they provide filtering of a signal to be operated in a semiconductor device.

In a second embodiment, the further element is provided on the second side of the semiconductor substrate. This side is available for patterning and processing after the thinning of the substrate.

The encapsulation may include a glass plate in this example, but that is not strictly necessary. Good results have also be obtained with the use of a resin layer, such as a polyimide. This polyimide may be applied in a photosensitive form, so that the grooves can be provided photolithographically. Additionally, terminals may be applied on top of such a resin layer.

Most suitably, trenches are defined in the second side of the semiconductor substrate. The trenches can be filled so as to constitute capacitors, batteries or also memory elements. Power transistors of the trench type may be provided alternatively. However, it is highly suitable in that case to provide a heat dissipation structure to the outside of the package.

In a suitable implementation of such trench devices, the semiconductor substrate comprises a highly doped region below a lowly doped region. The highly doped layer may then be used as one electrode of the trench devices. This is particularly the ground electrode, and it may be one electrode for all devices. A contact to this highly doped region can be provided either at the first side or at the second side of the semiconductor substrate or at both sides. Any connection through the lowly doped region may be provided with a deep diffusion. It is observed for clarity that a highly doped region generally is understood to have a charge carrier density of at least 10¹⁸/cm³, and preferably even 10¹⁹/cm³ or more. A lowly doped region generally is understood to have a charge carrier density of at most 10¹⁶/cm³.

In a third, most suitable embodiment, electric elements are provided both on the surface of the plate and on the second side of the semiconductor substrate. This allows to integrate more complex functions, for which different kinds of discrete elements are needed.

In a first example, an energy-scavenging element is provided together with an energy-storage element. This scavenging and storage combination allows to drive the integrated circuit on the first side of the semiconductor substrate. Examples of energy-scavenging elements are solar cells, Peltier elements and elements that convert vibrational energy into electrical energy. Although the amount of energy obtained with energy-scavenging is not ultimately high, this is generally sufficient for circuits that operate only during a relatively short period in time.

In a second example, an inductor is provided together with a capacitor. This combination could be enlarged with further inductors and/or capacitors to obtain any kind of passive filter. Particularly if present on glass or another insulating plate, the quality factor of the inductor will be good. Also, with the use of trench capacitors, the available capacitance is relatively high.

The metallization of the groove to which the conductor track of the further element is coupled, may well be corresponding to the other metallizations defined between the circuit and the terminals on the outside of the encapsulation. In some cases, it is desired that this metallization is even provided with a terminal. That is however not necessary, and depends on the specific application.

In a basic version of the technology, all metallizations extend from the carrier to the encapsulation. This has the advantage of a proper adhesion, and a more standardized manufacture. The resolution of the metallizations may however be increased with the use of a technique for three-dimensional lithography. This technique also allows the manufacture of metallizations that do not extend completely from the encapsulation to the carrier.

In case of higher resolution, it is suitable to fill the grooves with a protecting material. Preferably, this protecting material adheres well to the material at the side face of the groove, usually an epoxy or the like.

It is however observed for clarity that no higher resolution is needed for the implementation of the invention. The further element, optionally with the third element, is generally a filter or a sensor in the widest sense, including also solar cells, antennas, decoupling capacitors, and LC-circuits. Such filters and sensors are generally applied with circuits that have a limited number of terminals only. Examples are control ICs, amplifiers, identification transponders, and ICs for detection and elaboration of values measured by sensors. A limited number is here less than 100, but preferably much less, such as 20 or less.

The conductor tracks that are used in the invention, suitably have a sufficient ductility. This reduces the power needed during the provision of the grooves through the conductor tracks. Additionally, it allows a certain amount of stress-release. Particularly suitable materials are aluminum and aluminum alloys.

The further element and the corresponding conductor track preferably have a passivation layer that covers them. Thus passivation layer additionally improves adhesion to the adhesive, which is for instance an epoxy-material. Suitable materials for the passivation layer are for instance silicon oxide, silicon nitride, silicon oxynitride, but oxides of other metals can be applied alternatively.

The metallizations are chosen to be of a metal or alloy that forms a good electrical contact with the conductor tracks. Suitable materials include nickel, aluminum or an aluminum alloy.

Manufacture of the first embodiment of the invention is suitably achieved on wafer level, in that the second side of the semiconductor substrate is processed to define at least one electrical element after the substrate is attached to a carrier and the substrate has been thinned. The processing involves thin film techniques known per se.

Manufacture of the second embodiment of the invention is suitably achieved on wafer level, in that the encapsulation comprises a plate with at least one element on an inner side. The inner side is herein that side that is to be integrated with the semiconductor substrate such as to face the second side of the semiconductor substrate. The plate may be of insulating or semiconductor material. In the latter case, it is suitably provided with an insulating layer on its outer side, so as to isolate contact pads thereon from the element on and/or in the semiconductor substrate.

These and other aspects of the device of the invention will be further elucidated with reference to the figures, in which:

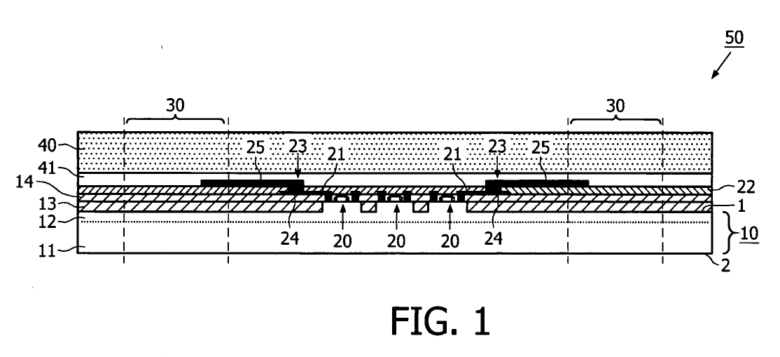

FIG. 1-4 shows in cross-sectional views steps in the method leading to a first embodiment of the device;

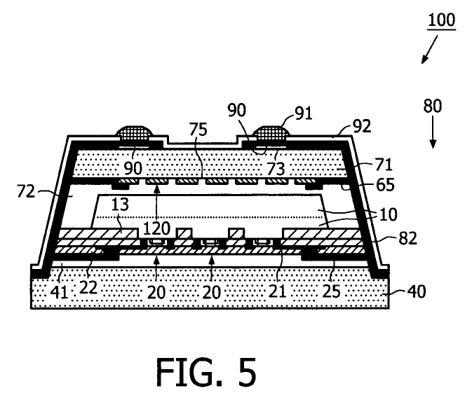

FIG. 5 shows in cross-sectional view a second embodiment of the device, and

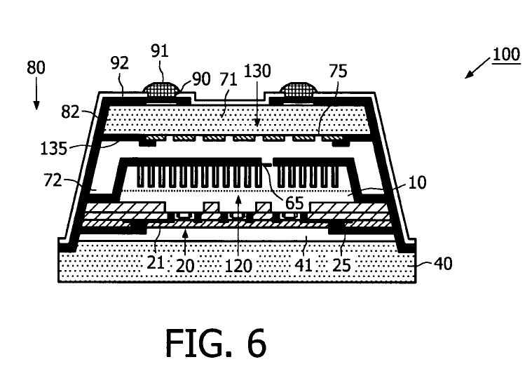

FIG. 6 shows in cross-sectional view a third embodiment of the device.

The Figures are not drawn to scale and are purely diagrammatical. The same reference numerals in different figures refer to the same or corresponding parts.

FIG. 1 shows diagrammatically and in cross-sectional view a first step of the method leading to the invention. The substrate 10 has a first side 1 and a second side 2. It comprises in this case a p⁺⁺-substrate layer 11, with a charge carrier density of at least 10¹⁸/cm³ and preferably more. A p⁻epitaxial layer 12 is grown on the p⁺⁺-substrate. As the skilled person will understand, the charge carriers could be of the opposite type, e.g. n instead of p. The substrate 10 is covered by a thermal oxide layer 13, which is formed in the usual manner. At the first side 1 of the substrate 10, semiconductor elements 20 have been defined. In this example, the semiconductor elements 20 are field effect transistors such as ordinarily part of a CMOS integrated circuit. Interconnects 21 enable the contacting of the elements 20 as well as the mutual coupling according to a predefined circuit design. Although not indicated here, the interconnects 21 generally form a multilayer structure. These interconnects 21 are covered by a passivation layer 22, with apertures 23 to expose contact pads 24. Conductors 25 are provided on the passivation layer 22. These conductors 25 extend to zones 30. These zones 30 will be removed in a later step of the process to define grooves. The substrate 10 is then attached to a carrier 40 with an adhesive 41, resulting in a subassembly 50. This carrier 40 is in this example a glass plate, but could alternatively be any ceramic or semiconductor material.

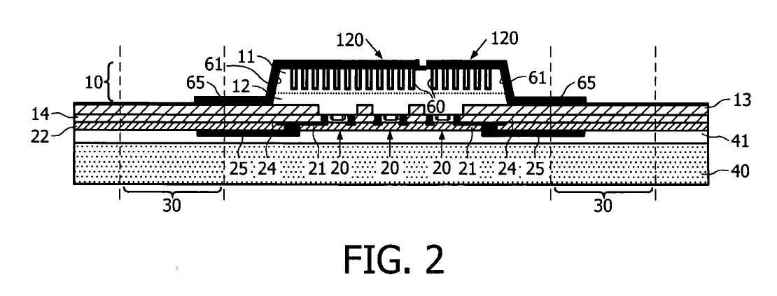

FIG. 2 shows the subassembly 50 after further process steps in which the further element 120 is defined. In this example, the further element 120 is defined at the second side 2 of the semiconductor substrate 10. The manufacture starts with the thinning of the substrate 10 from its second side 2 to approximately 20-100 microns. In this example, a reduction to a thickness of about 50-70 microns is appropriate. Conventional techniques are used for the thinning operation, such as grinding and wet-etching. The substrate 10 is then etched further so as to remove it completely or substantially completely in the zones 30 and adjacent to these zones. Additionally, trenches 60 are defined in the substrate 10. The trenches 60 may be defined simultaneously with the removal of the substrate in the zones 30 with reactive ion etching. Alternatively, the removal of the substrate in the zones may be achieved with wet-chemical etching through a mask. While the latter technique has the disadvantage that an additional mask is needed and more process steps are applied, it may have the advantage that the slope of the side faces 61 is less steep, enabling a better coverage by the conductor tracks to be deposited.

The definition of the trenches 60 is followed by the deposition of material into the trenches to define the further element 120. In this example, the p⁺⁺-substrate layer 11 is herein used one of the electrodes. The dielectric material is for instance a stack of oxide, nitride and oxide and the top electrode is polysilicon. The construction of the further element as a capacitor is further disclosed in F. Roozeboom et al, “High-density, Low loss capacitors for Integrated RF decoupling”, Int. J. Microcircuits and Electronic Packaging, 24(3), 2001, pp. 182-196. The use of these trenches 60 for batteries is known from WO-A 2005/27245. A suitable number of trenches 60 is placed in parallel to create the element 120 with the desired capacitance or energy storage. Conductor tracks 65 are then defined extending from the further element 120 to the zones 30 along the created side faces 61 of the substrate island 10. The tracks suitably comprise aluminum or an aluminum alloy and are preferably covered by a passivation layer (not shown).

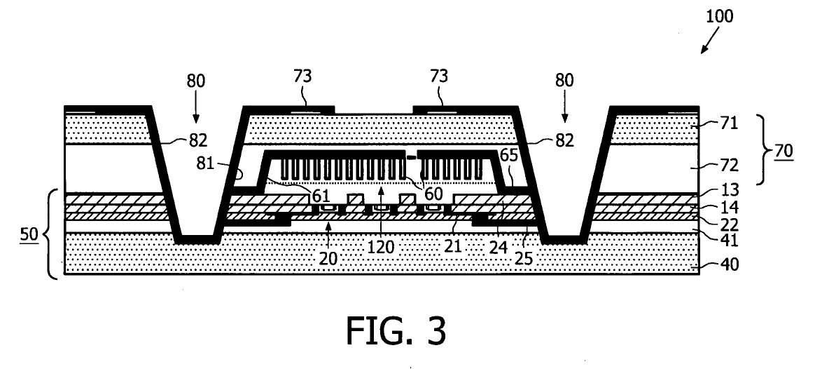

FIG. 3 shows the resulting device 100 after an encapsulation 70 has been applied to the subassembly 50, and after grooves 80 have been made in the zones predefined thereto. The encapsulation 70 comprises in this example a glass plate 71 and an adhesive 72. The adhesive 72 is suitably an epoxy, but could alternatively be an acrylate or also a resin such as a polyimide. Alternatively, the encapsulation 70 may be merely composed of a resin layer. The adhesive 72 also extends adjacent to the substrate island 10, therewith planarizing the subassembly 50. Compliant material 73 allowing stress release is deposited on the glass plate 71 at the locations where terminals 90 are to be provided, before the grooves 80 are made. The grooves 80 are preferably provided in a sawing step. This has the advantage of speed and low cost. Provision of the grooves by powder blasting, laser ablation or another technique is however not excluded. The grooves 80 are provided with side faces 81 on which the conductor tracks 25, 65 are exposed, e.g. with their side faces. A metallization 82 is then applied in the grooves 80, and adheres to the side faces 81 thereof. The conductor tracks 25, 65 are electrically connected to this metallization 82. The metallization 82 extends in this example from the carrier 40 to the encapsulation 70.

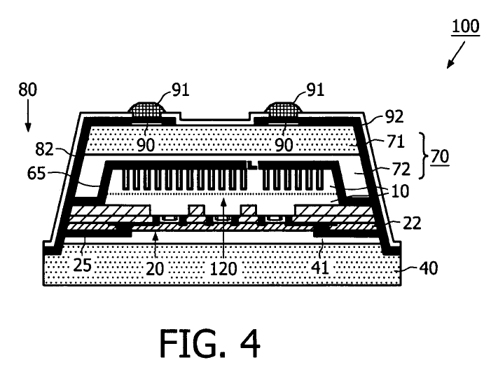

FIG. 4 shows the device 100 after the final steps in which solder balls 91 are applied to the terminals 90. These terminals 90 are defined by deposition and patterning of a solder mask 92. The solder balls 91 are generally applied onto a further underbump metallization. However, this is not strictly necessary, if the metallization 82 is wettable for the solder and if it is sufficiently thick. Before the solder mask 92 is applied, the grooves 80 may be filled with a resin. Finally, the individual devices 100 are individualized by dicing the carrier 40.

FIG. 5 shows in cross-sectional and diagrammatical view a second example of the device 100. Herein, the further element 120 is not defined on the second side 2 of the semiconductor substrate 10, but on the inner side 75 of a plate 71, in this case a glass plate 71. The further element 120 is in this example a thermo-electric generator, but may be alternatively an inductor, an antenna, a thin film circuit defined on the glass plate 71.

FIG. 6 shows in cross-sectional and diagrammatical view a third example of the device 100. This device 100 comprises a further element 120 that is defined on the second side 2 of the semiconductor substrate 10, and additionally a third element 130 defined on the inner side 75 of a plate 71 in the encapsulation 70, with a conductor track 135. The further element 120 and the third element 120 are herein mutually coupled by a metallization 182. In this example, the metallization 182 does not extend to a conductor track 25 of the circuit of semiconductor elements 20.

Summarizing, the electronic device comprises a semiconductor substrate 10 with at a first side 1 a circuit of semiconductor elements 20. The substrate 10 is present between a carrier 40 and an encapsulation 70, so that the first side 1 of the substrate 10 faces the carrier 40. The circuit of semiconductor elements 20 is coupled with conductor tracks 25 to a metallization 82 in a groove 80 in the encapsulation 70, which metallization 82 extends to terminals 90 at an outside of the encapsulation 70. At least one further electrical element 120 is defined between the first side 1 of the semiconductor substrate 10 and the encapsulation 70. This further element 120 is provided with at least one conductor track 65 extending to the metallization 82 in the groove 80 so as to incorporate the further element 120 in the circuit of semiconductor elements 20 on the first side 1 of the substrate 10.

### REFERENCE NUMERALS

1 first side of substrate 10
2 second side of the substrate 10
10 semiconductor substrate
11 p⁺⁺-layer of semiconductor substrate 10
12 p⁻epitaxial layer of semiconductor substrate 10
13 oxide on top of semiconductor substrate 10
20 semiconductor element
21 interconnect
22 passivation layer
23 aperture in the passivation layer 22
24 contact pad exposed by the aperture 23
25 conductor track
30 zone in which grooves are to be provided.
40 carrier
41 adhesive
50 subassembly of carrier 40 and substrate 10
60 trench
61 side face of island-shaped substrate 10
65 conductor track
70 encapsulation
71 plate, preferably glass plate
72 adhesive
73 compliant material provided on encapsulation
75 inner side of glass plate
80 groove
81 side face of groove 80
82 metallization in groove 82
90 terminal
91 solder ball
92 solder mask
100 electronic device
120 further element
130 third element
135 conductor track to further element
182 metallization coupling further element with third element

1. An electronic device comprising a semiconductor substrate (10) having a first side, at which first side (1) a circuit of semiconductor elements (20) is configured, which substrate is present between a carrier (40) and an encapsulation (70), so that the first side (1) of the substrate (10) faces the carrier (40), wherein conductor tracks (25) are present on the first side (1) of the semiconductor substrate (10) and metallized grooves (80, 82) are present in the encapsulation (70), extending through the substrate (10) to the carrier (40) and being electrically coupled to said conductor tracks (25, 65), for connecting the elements to terminals (90) configured on an outside of the encapsulation (70), characterized in that at least one further electrical element (120) is configured between the first side (1) of the semiconductor substrate (10) and the encapsulation (120), wherein the further element comprises at least one conductor track (65) extending to the groove (80) and being electrically coupled to the metallization (82) of the groove incorporating the further element (120) in the circuit on the first side (1) of the substrate, and the further electrical element (120), in at least a portion, defines a space between itself and the semiconductor elements (20), which space comprising the semiconductor substrate (10).

2. An electronic device as claimed in claim 1, wherein the encapsulation comprises a plate (71) and the further element is defined on one face of the plate (71), which face faces a second side (2) of the substrate facing away from the carrier (40).

3. An electronic device as claimed in claim 2, wherein the further element is a magnetoresistive sensor.

4. An electronic device as claimed in claim 2, wherein the further element is a bulk acoustic wave filter.

5. An electronic device as claimed in claim 1, wherein the further element is present at a second side (2) of the substrate, facing away from the first side.

6. An electronic device as claimed in claim 5, wherein the further element comprises at least one trench in the second side of the substrate.

7. An electronic device as claimed in claim 6, wherein the semiconductor substrate is at its second side provided with a highly doped layer that acts as one electrode of the further element and is coupled to a conductor track on at least one of the first and the second side of the substrate.

8. An electronic device as claimed in claim 6, wherein the element is either a battery or a capacitor.

9. An electronic device as claimed in claim 5, wherein the encapsulation comprises a plate and a third element with a conductor track extending between the element and a metallization of a groove are defined on one face of the plate, which face faces the second side of the substrate, which metallization interconnects the third element with the further element.

10. An electronic device as claimed in claim 9, wherein the third element is a energy-scavenging element and the further element is able of storage of the energy generated by the third element.

11. An electronic device as claimed in claim 9, wherein the third element is an inductor and the further element is a capacitor.
